(19) United States
(12) Patent Application Publication
(10) Pub. No.: US 2010/0300730 A1
(43) Pub. Date: Dec. 2, 2010

(54) Electronic apparatus and flexible printed circuit thereof

(75) Inventor: Hung-sen Yang, Taipei Hsien (TW)

Correspondence Address: BACON & THOMAS, PLLC, 625 SLATERS LANE, FOURTH FLOOR, ALEXANDRIA, VA, 22314-1176, US

(73) Assignee: Wistron Corporation, Taipei Hsien (TW)

(21) Appl. No.: 12/588,648

(22) Filed: Oct. 22, 2009

(30) Foreign Application Priority Data
May 26, 2009 (TW) 098117547

(51) Int. Cl. H05K 1/00

(52) U.S. Cl. 174/254

(57) ABSTRACT

A flexible printed circuit for an electronic apparatus is disclosed. The flexible printed circuit is capable of being bended along a radial direction. The flexible printed circuit comprises a first base film, a first copper foil layer, and a cover layer. The first copper foil layer is disposed on the first base film, and the cover layer is disposed on the first copper foil layer. The cover layer comprises an opening, and the first copper foil layer forms an exposed area via the opening. At least one boundary is formed between the exposed area and the cover layer, wherein the at least one boundary is not a single straight line substantially parallel to the radial direction.

### BACKGROUND OF THE INVENTION

1. Field of the Invention

The present invention relates to a flexible printed circuit; more particularly, to a flexible printed circuit capable of reducing cracking possibility during a bending assembly process.

2. Description of the Related Art

Generally, a portable electronic apparatus is designed to be as compact as possible in order to provide convenience and portability. As a result, available interior space of the portable electronic apparatus is very limited. Therefore, a light-weight and thin flexible printed circuit (FPC) is used as an application of an interior component, or a connection among components. In order to improve electrostatic discharge (ESD) efficiency and reduce electromagnetic interference (EMI) influence of the portable electronic apparatus, a conventional design of the flexible printed circuit 200 is shown in FIG. 1. The flexible printed circuit 200 is made by superimposing multiple layers of materials. After a process, a partial area of an insulation protective layer 210 on the surface of the flexible printed circuit 200 would be removed, such that a copper foil material located underneath would be exposed accordingly. Then a bare copper area 220 is formed for providing a conducting or grounding function. Further, a boundary 230 (i.e. the bold black line as shown in FIG. 1) between the bare copper area 220 and the insulation protective layer 210 is designed as a straight line substantially parallel to any radial direction S of the flexible printed circuit 200.

However, because the thickness of the bare copper area 220 is relative thin due to its lack of a covered insulation protective layer 210, the hardness of the bare copper area 220 is softer than other areas with the insulation protective layer 210 covered thereon. As shown in FIG. 2, during an assembly process that the flexible printed circuit 200 is being bended along a radial direction, the stress would often be concentrated to the boundary 230 between the bare copper area 220 and the insulation protective layer 210 because the area with the insulation protective layer 210 covered thereon has a higher hardness. A sharp bending angle, rather than a smooth curved angle, would be formed when the flexible printed circuit 200 is being bended. Therefore, the boundary 230 between the bare copper area 220 and the insulation protective layer 210 of the flexible printed circuit 200 is easily cracked and damaged.

Therefore, there is a need to provide a flexible printed circuit thereof to mitigate and/or obviate the aforementioned problems.

### SUMMARY OF THE INVENTION

It is an object of the present invention to provide a flexible printed circuit capable of reducing cracking possibility during a bending assembly process.

To achieve the abovementioned object, the present invention provides a flexible printed circuit for an electronic apparatus. The flexible printed circuit is capable of being bended along a radial direction. The flexible printed circuit comprises a first base film, a first copper foil layer and a cover layer. The first copper foil layer is disposed on the first base film, and the cover layer is disposed on the first copper foil layer. The cover layer comprises an opening, and the first copper foil layer forms an exposed area via the opening. At least one boundary is formed between the exposed area and the cover layer, wherein the at least one boundary is not a single straight line substantially parallel to the radial direction. Accordingly, when the flexible printed circuit of the present invention is being bended along a radial direction, the flexible printed circuit will not be easily cracked due to the situation that the stress is concentrated to the hard/soft boundary formed between the exposed area and the cover layer.

Other objects, advantages, and novel features of the invention will become more apparent from the following detailed description when taken in conjunction with the accompanying drawings.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings, wherein similar reference numerals denote similar elements throughout the several views:

FIG. 1 illustrates a top view of a flexible printed circuit according to a known prior art.

FIG. 2 illustrates a schematic drawing showing the flexible printed circuit bended along a radial direction according to the known prior art.

FIG. 3 illustrates a structural schematic drawing of a flexible printed circuit according to a first embodiment of the present invention.

FIG. 4 illustrates a top view of the flexible printed circuit according to the first embodiment of the present invention.

FIGS. 5(a) and 5(b) illustrate top views of the flexible printed circuit with different forms of boundaries according to a second embodiment of the present invention.

FIGS. 6(a), 6(b) and 6(c) illustrate top views of the flexible printed circuit with different forms of boundaries according to a third embodiment of the present invention.

FIG. 7 illustrates a top view of the flexible printed circuit with a different form of boundary according to a fourth embodiment of the present invention.

FIG. 8 illustrates a structural schematic drawing of the flexible printed circuit according to a fifth embodiment of the present invention.

FIG. 9 illustrates a schematic drawing of an electronic apparatus according to the present invention.

### DETAILED DESCRIPTION OF THE PREFERRED EMBODIMENT

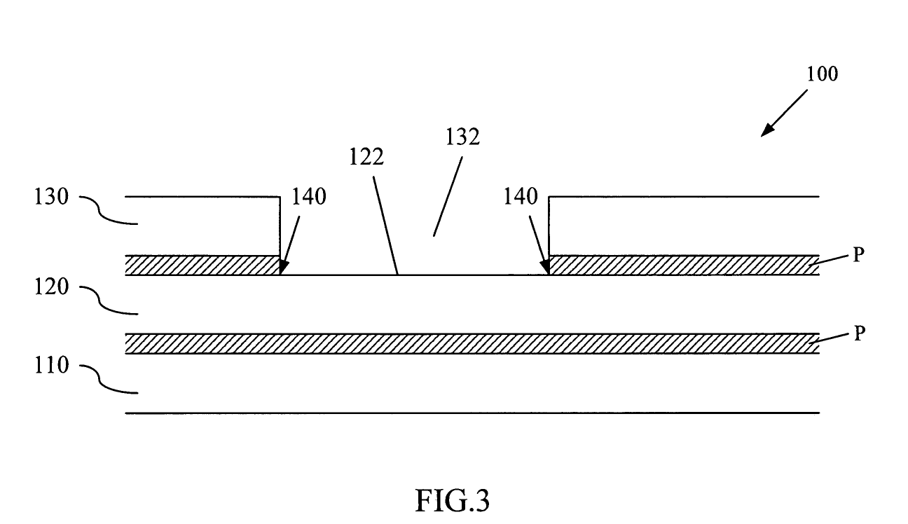

Please refer to FIG. 3 for a structural schematic drawing of a flexible printed circuit 100 according to a first embodiment of the present invention. As shown in FIG. 3, the flexible printed circuit 100 of the present invention is applied in an electronic apparatus (not shown). The flexible printed circuit 100 is capable of being bended along a radial direction S to be placed in the electronic apparatus for an assembly process. The electronic apparatus can be, but is not limited to, a mobile phone, a personal digital assistant (PDA), a laptop computer, or the like. In this embodiment, the flexible printed circuit 100 of the present invention comprises a first base film 110, a first copper foil layer 120 and a cover layer 130. The first copper foil layer 120 is disposed on the first base film 110, and the cover layer 130 is disposed on the first copper foil layer 120. Each of the abovementioned layers are combined with each other via an adhesive material P. The cover layer 130 comprises an opening 132, and the first copper foil layer 120 forms an exposed area 122 via the opening 132, such that the flexible printed circuit 100 of the present invention can provide a conducting or grounding function via the exposed area 122. At least one boundary 140 is formed between the exposed area 122 and the cover layer 130. According to different design requirements, the first copper foil layer 120 of the flexible printed circuit 100 of the present invention can be made of either a solid copper material or a mesh copper material, so as to provide flexible printed circuits with different hardness/softness. The first base film 110 is used as a main body of the flexible printed circuit 100 for providing an insulation function; the first copper foil layer 120 is used as an electrically-conductive line; and the cover layer 130 is used as insulation protection for the first copper foil layer 120.

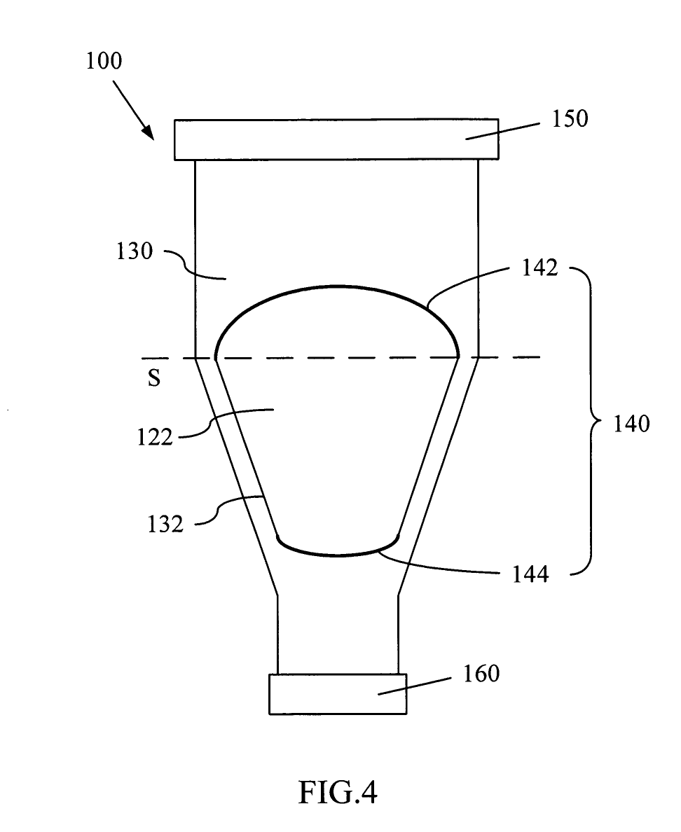

Please refer to FIG. 4 for a top view of the flexible printed circuit 100 according to the first embodiment of the present invention. As shown in FIG. 4, the at least one boundary 140 is formed between the exposed area 122 and the cover layer 130, for example, the bold black lines depicted in FIG. 4. Wherein the at least one boundary 140 is not a single straight line substantially parallel to the radial direction S.

The flexible printed circuit 100 of the present invention further comprises a first connection interface 150 and a second connection interface 160 used for respectively connecting with different components in the electronic apparatus.

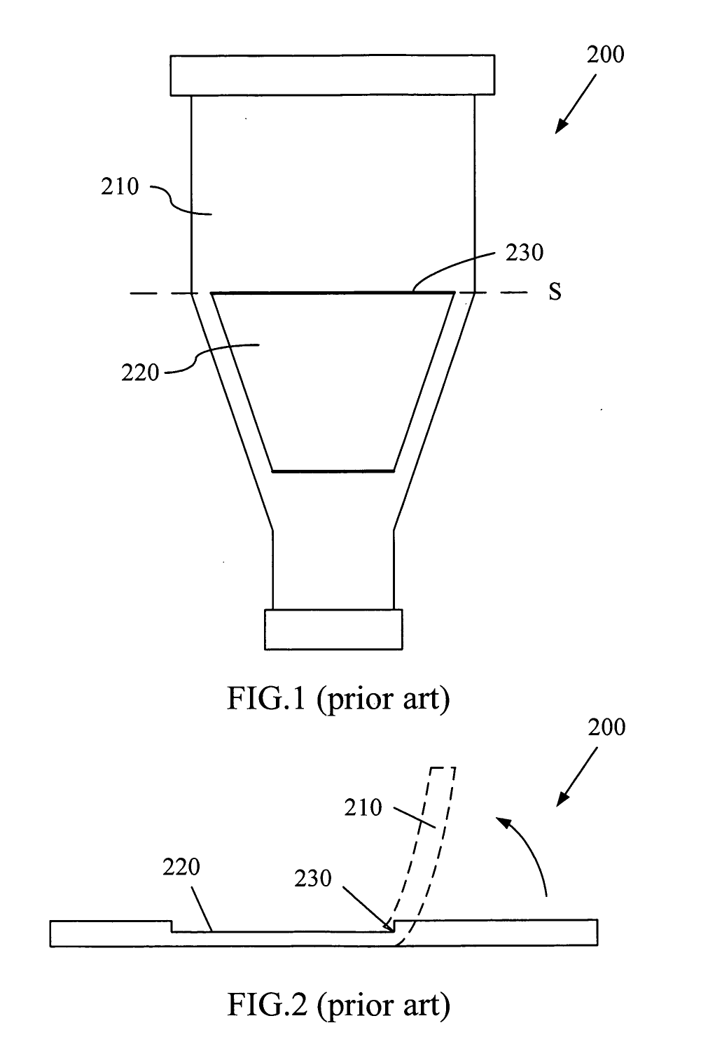

The at least one boundary 140 comprises a first boundary 142 close to the first connection interface 150 and/or a second boundary 144 close to the second connection interface 160, wherein each boundary 140 is a continuous line. According to different designs, the boundary 140 can be, but is not limited to, at least one curved line, a multi-sided structure formed by a plurality of adjacent straight lines, or a combination of at least one curved line and at least one straight line, so as to avoid the conventional design of a known boundary 230 as shown in FIG. 1 (i.e., the design that the boundary 230 is in the form of a single straight line substantially parallel to the radial direction S). In this embodiment, each boundary 140 is in the form of an arc-shaped curved line. When the flexible printed circuit 100 of the present invention is being bended along the radial direction S, the variation of hardness/softness would not be concentrated to a single straight line, so as to reduce the impact caused by the stress as well as to increase usability and safety of the flexible printed circuit 100 of the present invention. Further, according to the aforementioned design, the surface area of the exposed area 122 can be increased so as to improve release rate of electrical signals.

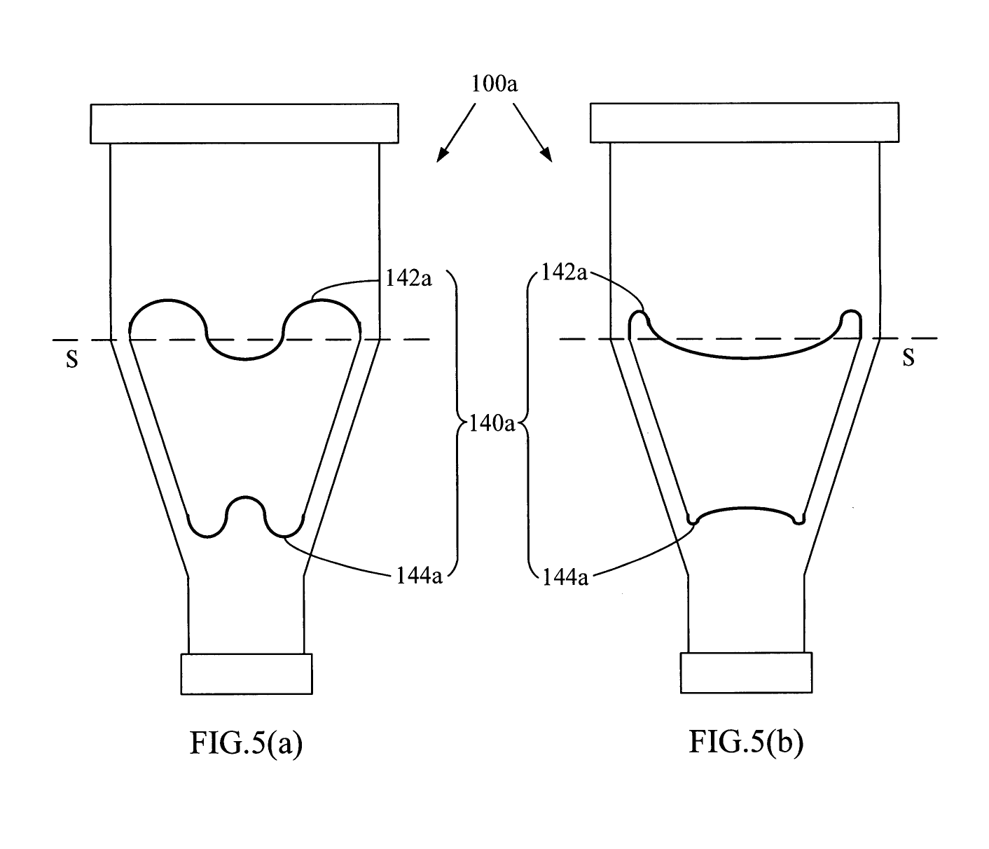

Please refer to FIGS. 5(a) and 5(b) for top views of the flexible printed circuit 100a with different forms of boundaries according to a second embodiment of the present invention. This embodiment is a variation of the above first embodiment. In this embodiment, the first boundary 142a of the flexible printed circuit 100a of the present invention is in the form of a continuous curved line. As shown in FIGS. 5(a) and 5(b), the first boundaries 142a can be designed as wave-shaped curved lines of different forms (such as a near M-shaped curved line or a near U-shaped curved line), and the crack-resistant function of the aforementioned embodiment can still be achieved. Likewise, the second boundary 144a can also be designed in similar forms. Please note that the at least one boundary 140a of the flexible printed circuit 100a of the present invention can be designed as other similar curved lines without being limited to the scope of this embodiment.

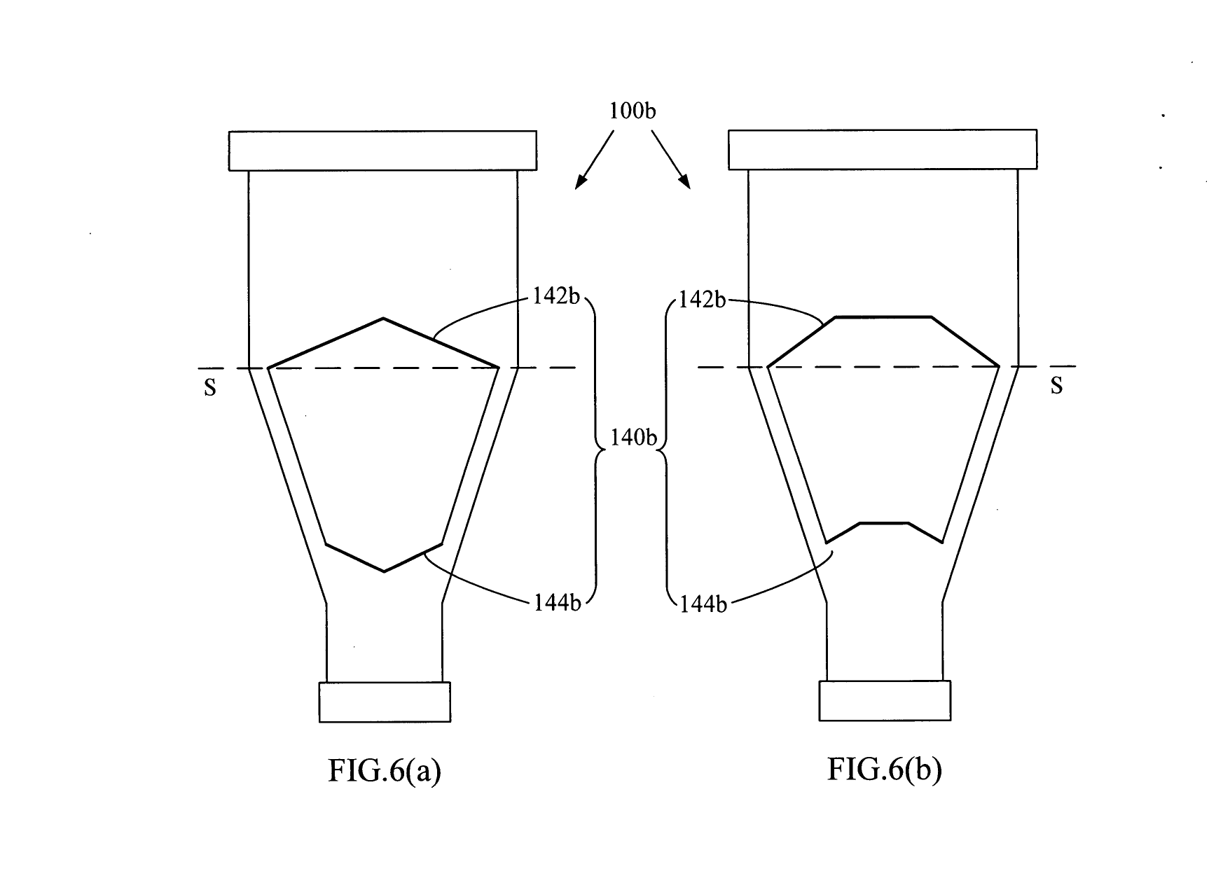

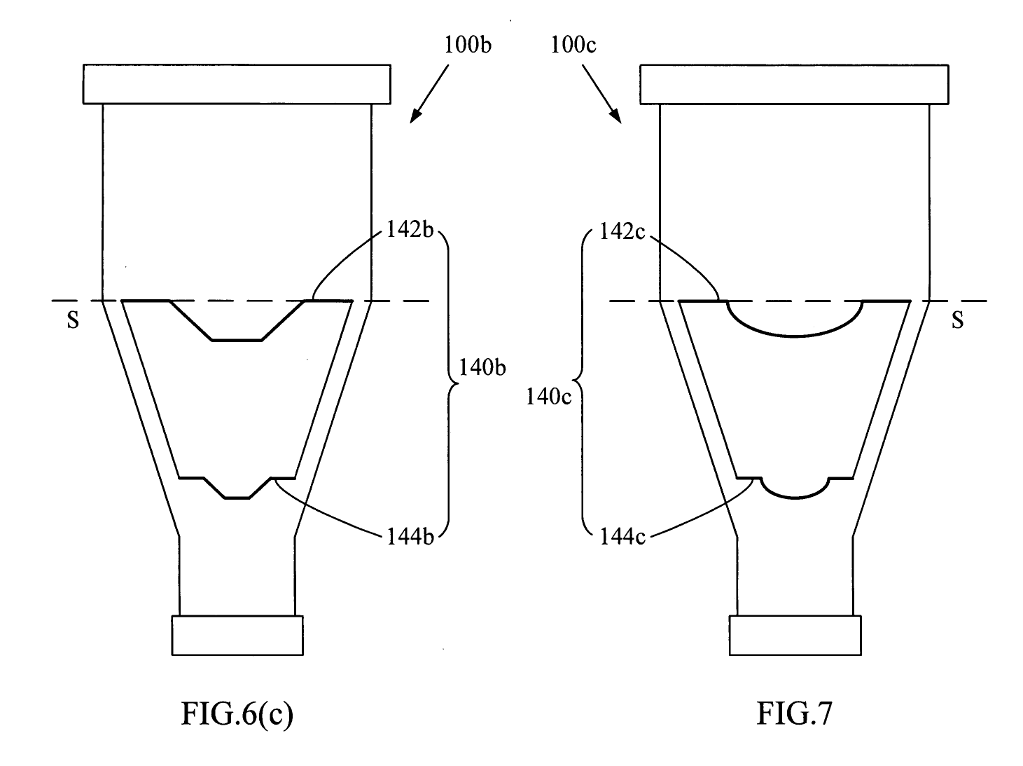

Please refer to FIGS. 6(a), 6(b) and 6(c) for top views of the flexible printed circuit 100b with different forms of boundaries according to a third embodiment of the present invention. This embodiment is a variation of the above embodiments. In this embodiment, the first boundary 142b of the flexible printed circuit 100b of the present invention is in the form of a multi-sided structure formed by a plurality of adjacent straight lines. As shown in FIG. 6(a), the first boundary 142b is designed as a two-sided structure with an included angle formed by connecting two adjacent straight lines; as shown in FIG. 6(b), the first boundary 142b is designed as a three-sided structure with two included angles formed by connecting three adjacent straight lines; or as shown in FIG. 6(c), the first boundary 142b is designed as a five-sided structure formed by connecting five adjacent straight lines. According to the above designs, the first boundary 142b is not in the form of a single straight line substantially parallel to the radial direction S as described in the known prior art. Therefore, the usability and safety of the flexible printed circuit 100b of the present invention can be assured. Likewise, the second boundary 144b can also be designed in similar forms. Please note that the at least one boundary 140b of the flexible printed circuit 100b of the present invention can be designed as other similar multi-sided structures formed by a plurality of straight lines without being limited to the scope of this embodiment.

Please refer to FIG. 7 for a top view of the flexible printed circuit 100c with a different form of boundary according to a fourth embodiment of the present invention. This embodiment is a variation of the above embodiments. In this embodiment, the first boundary 142c of the flexible printed circuit 100c of the present invention is in the form of a combination of at least one curved line and at least one straight line. As shown in FIG. 7, the first boundary 142c is in the form of a combination of two straight lines and one arc-shaped curved line, and the crack-resistant function of the aforementioned embodiments can still be achieved. Likewise, the second boundary 144c can also be designed in similar forms. Please note that the at least one boundary 140c of the flexible printed circuit 100c of the present invention can be designed as other similar combinations of at least one curved line and at least one straight line without being limited to the scope of this embodiment.

Further, each of the forms of boundaries described in the aforementioned embodiments can be combined together and applied in the same piece of flexible printed circuit, and the crack-resistant function of the present invention can still be achieved. It is not necessary that the shape of the first boundaries 142˜142c has to be symmetric to that of the second boundaries 144˜144c.

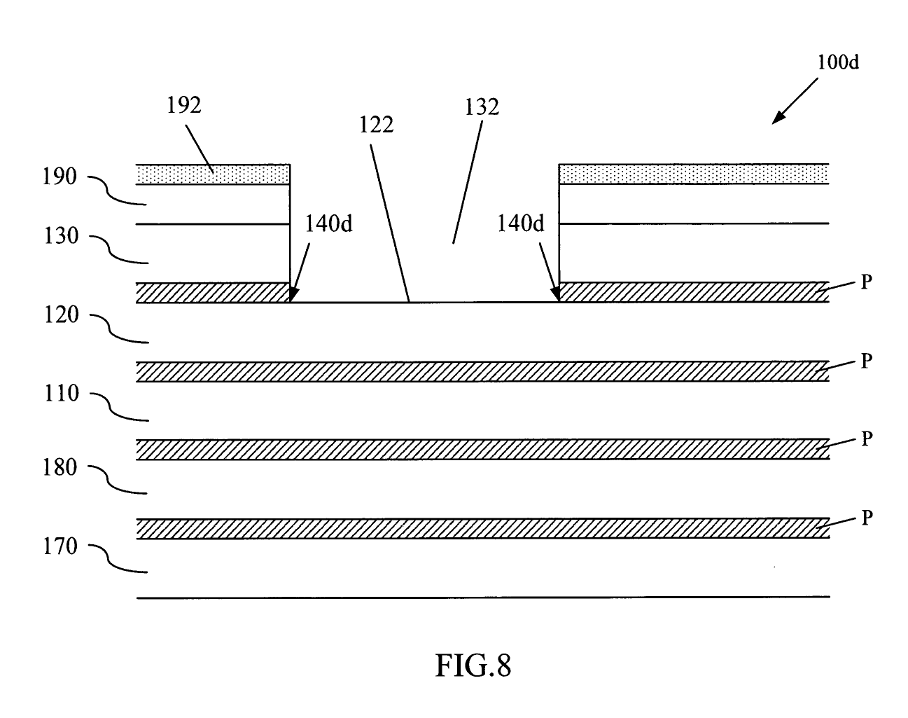

Please refer to FIG. 8 for a structural schematic drawing of the flexible printed circuit 100d according to a fifth embodiment of the present invention. As shown in FIG. 8, the flexible printed circuit 100d of the present invention further comprises a second base film 170 and a second copper foil layer 180. The second copper foil layer 180 is located between the second base film 170 and the first base film 110, wherein each of the layers are combined with each other via the adhesive material P. The second base film 170 is used as a main body of the flexible printed circuit 100d of the present invention for providing an insulation function; and the second copper foil layer 180 is used as an electrically-conductive line for providing signal line, grounding or shield functions. Accordingly, the flexible printed circuit 100d of the present invention forms a dual-layer line structure, and the at least one boundary 140d formed between the exposed area 122 and the cover layer 130 can be in the form of any of the abovementioned embodiments, such that the flexible printed circuit 100d of the present invention is not easily cracked.

Moreover, the flexible printed circuit 100d of the present invention further comprises a shield layer 190 disposed on the cover layer 130. The shield layer 190 is disposed on an area except the opening 132 of the cover layer 130, such that the exposed area 122 of the first copper foil layer 120 can be exposed. Therefore, the shield layer 190 can provide the first copper foil layer 120, except the exposed area 122, with an electromagnetic shield function. The shield layer 190 can be made of an aluminum foil material or a silver foil material. The flexible printed circuit 100d of the present invention can further comprises a solder mask layer 192 disposed on the shield layer 190 for protecting integrally the flexible printed circuit 100d of the present invention.

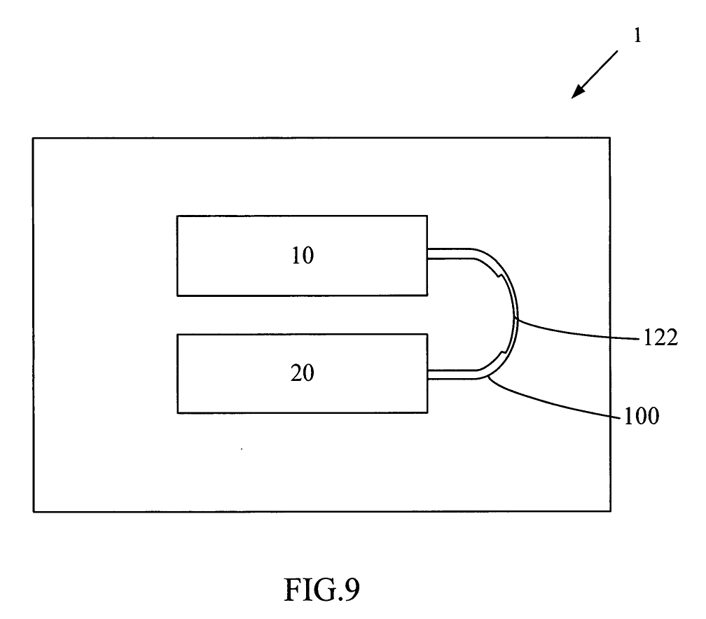

Please refer to FIG. 9 for a schematic drawing of an electronic apparatus 1 according to the present invention. As shown in FIG. 9, in this embodiment, the electronic apparatus 1 of the present invention comprises a first assembly 10, a second assembly 20 and an aforementioned flexible printed circuit 100. The flexible printed circuit electrically connects with the first assembly 10 and the second assembly 20, and the flexible printed circuit 100 is capable of being bended along a radial direction. The first assembly 10 or the second assembly 20 can be a printed circuit board, a multi-functional modular component or other electronic parts. The flexible printed circuit 100 can provide a conducting or grounding function via the exposed area 122. Further, according to the structure design of the aforementioned flexible printed circuit 100, when the flexible printed circuit 100 is being bended along the radial direction to be placed in the electronic apparatus 1, the flexible printed circuit 100 is not easily cracked or damaged. The electronic apparatus 1 of the present invention can also utilize the flexible printed circuits 100a-100d with different designs as described above without being limited to the scope of this embodiment.

Although the present invention has been explained in relation to its preferred embodiments, it is to be understood that many other possible modifications and variations can be made without departing from the spirit and scope of the invention as hereinafter claimed.

What is claimed is:

1. A flexible printed circuit, applied in an electronic apparatus, wherein the flexible printed circuit is capable of being bended along a radial direction, and the flexible printed circuit comprises:
a first base film;
a first copper foil layer, disposed on the first base film; and
a cover layer, disposed on the first copper foil layer, the cover layer comprising an opening, and the first copper foil layer forming an exposed area via the opening, at least one boundary formed between the exposed area and the cover layer, wherein the at least one boundary is not a single straight line substantially parallel to the radial direction.

2. The flexible printed circuit as claimed in claim 1, wherein the at least one boundary is at least one curved line, an arc-shaped curved line, a continuous curved line, or a wave-shaped curved line.

3. The flexible printed circuit as claimed in claim 1, wherein the at least one boundary is a multi-sided structure formed by a plurality of adjacent straight lines.

4. The flexible printed circuit as claimed in claim 1, wherein the at least one boundary is a combination of at least one curved line and at least one straight line.

5. The flexible printed circuit as claimed in claim 1, wherein the first copper foil layer is made of a solid copper material or a mesh copper material.

6. The flexible printed circuit as claimed in claim 1 further comprising a second base film and a second copper foil layer, wherein the second copper foil layer is located between the second base film and the first base film.

7. The flexible printed circuit as claimed in claim 6 further comprising a shield layer disposed on the cover layer.

8. The flexible printed circuit as claimed in claim 7, wherein the shield layer is made of an aluminum foil material or a silver foil material.

9. The flexible printed circuit as claimed in claim 7 further comprising a solder mask layer disposed on the shield layer.

10. The flexible printed circuit as claimed in claim 1 further comprising a first connection interface and a second connection interface, wherein the at least one boundary comprises a first boundary close to the first connection interface and a second boundary close to the second connection interface.

11. An electronic apparatus, comprising:
a first assembly;
a second assembly; and
a flexible printed circuit, used for electrically connecting with the first assembly and the second assembly, wherein the flexible printed circuit is capable of being bended along a radial direction, and the flexible printed circuit comprises:
a first base film;
a first copper foil layer, disposed on the first base film; and
a cover layer, disposed on the first copper foil layer, the cover layer comprising an opening, and the first copper foil layer forming an exposed area via the opening, at least one boundary formed between the exposed area and the cover layer, wherein the at least one boundary is not a single straight line substantially parallel to the radial direction.

12. The electronic apparatus as claimed in claim 11, wherein the at least one boundary is at least one curved line, an arc-shaped curved line, a continuous curved line, or a wave-shaped curved line.

13. The electronic apparatus as claimed in claim 11, wherein the at least one boundary is a multi-sided structure formed by a plurality of adjacent straight lines.

14. The electronic apparatus as claimed in claim 11, wherein the at least one boundary is a combination of at least one curved line and at least one straight line.

15. The electronic apparatus as claimed in claim 11, wherein the first copper foil layer is made of a solid copper material or a mesh copper material.

16. The electronic apparatus as claimed in claim 11, wherein the flexible printed circuit further comprising a second base film and a second copper foil layer, wherein the second copper foil layer is located between the second base film and the first base film.

17. The electronic apparatus as claimed in claim 16, wherein the flexible printed circuit further comprising a shield layer disposed on the cover layer.

18. The electronic apparatus as claimed in claim 17, wherein the shield layer is made of an aluminum foil material or a silver foil material.

19. The electronic apparatus as claimed in claim 17, wherein the flexible printed circuit further comprising a solder mask layer disposed on the shield layer.

20. The electronic apparatus as claimed in claim 11, wherein the flexible printed circuit further comprising a first connection interface and a second connection interface, wherein the at least one boundary comprises a first boundary close to the first connection interface and a second boundary close to the second connection interface.
